(19) United States
(12) Patent Application Publication
(10) Pub. No.: US 2018/0166470 A1
(43) Pub. Date: Jun. 14, 2018

(54) DISPLAY APPARATUS AND CONNECTING METHOD OF LIGHT EMITTING PART THEREOF

(71) Applicant: SEOUL VIOSYS CO., LTD., Ansan-si (KR)

(72) Inventor: Jong Hyeon Chae, Ansan-si (KR)

(21) Appl. No.: 15/835,362

(22) Filed: Dec. 7, 2017

(30) Foreign Application Priority Data
Dec. 7, 2016 (KR) 10-2016-0165631

(51) Int. Cl. H01L 27/12; G02F 1/1343; G02F 1/1333; G02F 1/1335

(52) U.S. Cl. CPC H01L 27/1214; G02F 1/133603; G02F 1/133345; G02F 1/1343

(57) ABSTRACT

A display apparatus and a method of connecting electrodes thereof. The display apparatus includes: a light emitting part including a plurality of light emitting diodes regularly arranged thereon; and a TFT panel part including a plurality of TFTs driving the plurality of light emitting diodes, wherein the light emitting part includes a substrate; a plurality of electrodes regularly arranged on the substrate; the plurality of light emitting diodes regularly arranged on the substrate and separated from the plurality of electrodes; and a plurality of printed connection electrodes electrically connecting the plurality of electrodes to the plurality of light emitting diodes, respectively. The display apparatus employs micro-light emitting diodes formed of nitride semiconductors to realize high resolution, low power consumption and high efficiency. Accordingly, the display apparatus can be applied to various apparatuses including a wearable apparatus.

### TECHNICAL FIELD

The present invention relates to a display apparatus and a method of connecting electrodes thereof, and more particularly, to a display apparatus employing micro-light emitting diodes and a method of connecting electrodes thereof.

### BACKGROUND

A light emitting diode refers to an inorganic semiconductor device that emits light through recombination of electrons and holes. In recent years, light emitting diodes have been used in various fields including displays, automobile lamps, general lighting, and the like, and application fields of such light emitting diodes have expanded.

Light emitting diodes have various advantages such as long lifespan, low power consumption, and rapid response. Thus, a light emitting device using a light emitting diode can be used as a light source in various fields.

Recently, smart TVs or monitors realize colors using a thin film transistor liquid crystal display (TFT-LCD) panel and use light emitting diodes as a light source for a backlight unit for color realization. In addition, a display apparatus is often manufactured using organic light emitting diodes (OLEDs).

As a backlight light source of a TFT-LCD panel, one LED is used to supply light to many pixels of the TFT-LCD panel. In this structure, since the backlight light source must be kept on regardless of colors displayed on a screen of the TFT-LCD panel, the TFT-LCD panel suffers from constant power consumption regardless of brightness of a displayed screen.

In addition, although power consumption of an OLED display apparatus has been continuously reduced due to technological development, OLEDs still have much higher power consumption than LEDs formed of inorganic semiconductors and thus have low efficiency.

Moreover, a PM drive type OLED display apparatus can suffer from deterioration in response speed upon pulse amplitude modulation (PAM) of the OLED having large capacitance. In addition, the PM drive type OLED display apparatus can suffer from deterioration in lifespan upon high current driving through pulse width modulation (PWM) for realizing a low duty ratio.

Moreover, an AM driving type OLED display apparatus requires connection of TFTs for each pixel, thereby causing increase in manufacturing costs and non-uniform brightness according to characteristics of TFTs.

### SUMMARY

The present invention is to provide a display apparatus employing micro-light emitting diodes having low power consumption to be applicable to a wearable apparatus, a smartphone or a TV.

The present invention is to provide a method of connecting electrodes for supplying power to light emitting diodes of a display apparatus.

In accordance with one exemplary embodiment of the present invention, a display apparatus includes: a light emitting part including a plurality of light emitting diodes regularly arranged thereon; and a TFT panel part including a plurality of TFTs driving the plurality of light emitting diodes, wherein the light emitting part includes a substrate; a plurality of electrodes regularly arranged on the substrate; the plurality of light emitting diodes regularly arranged on the substrate and separated from the plurality of electrodes; and a plurality of printed connection electrodes electrically connecting the plurality of electrodes to the plurality of light emitting diodes, respectively.

The display apparatus may further include a printed insulating portion interposed between the plurality of electrodes and the plurality of light emitting diodes, wherein the plurality of printed connection electrodes may be disposed on the printed insulating portion.

The printed insulating portion may have the same or greater thickness than the plurality of light emitting diodes, and may be formed by conformal coating.

The printed insulating portion may be formed of a transparent material.

Each of the printed connection electrodes may electrically connect an electrode to a light emitting diode adjacent to the electrode among the plurality of electrodes and the plurality of light emitting diodes, and the plurality of printed connection electrodes may be formed of a transparent material.

The printed insulating portion or the printed connection electrodes may be formed by printing by a micro-ink jet printer.

Each of the electrodes may be a second electrode and each of the light emitting diodes may include a first conductivity type semiconductor layer, a second conductivity type semiconductor layer, an active layer interposed between the first and second conductivity type semiconductor layers, and a first electrode disposed on the second conductivity type semiconductor layer.

In accordance with another exemplary embodiment of the present invention, a method of connecting electrodes of a display apparatus includes: printing a printed insulating portion between a plurality of light emitting diodes and a plurality of electrodes regularly arranged on a substrate using a micro-ink jet printer; and printing a plurality of printed connection electrodes on the printed insulating portion using a micro-ink jet printer to electrically connect the plurality of light emitting diodes to the plurality of electrodes, respectively.

The printed insulating portion may be formed of a transparent insulating epoxy and the printed connection electrodes may be formed of a transparent conductive epoxy or may be formed of at least one of ITO, ZnO and Ag nanowires.

Printing the printed insulating portion may include printing a plurality of printed insulating portions between the plurality of light emitting diodes and the plurality of electrodes, respectively, and the printed insulating portions may be spaced apart from each other.

The plurality of printed connection electrodes may be spaced apart from each other.

According to the present invention, the display apparatus employs micro-light emitting diodes formed of nitride semiconductors to realize high resolution, low power consumption and high efficiency. Accordingly, the display apparatus can be applied to various apparatuses including a wearable apparatus.

Furthermore, it is possible to provide a convenient electrical connection of electrodes of the micro-light emitting diodes by printing a transparent conductor epoxy between the electrodes using a micro-ink jet printer for connection of the electrodes for supplying power to the micro-light emitting diodes of the display apparatus.

### BRIEF DESCRIPTION OF DRAWINGS

FIG. 1 is a cross-sectional view of a display apparatus according to one exemplary embodiment of the present invention.

FIG. 2 to FIG. 4 are views illustrating a process of connecting electrodes of a light emitting part of the display apparatus according to the exemplary embodiment of the present invention.

### DETAILED DESCRIPTION

Exemplary embodiments of the present invention will be described in more detail with reference to the accompanying drawings.

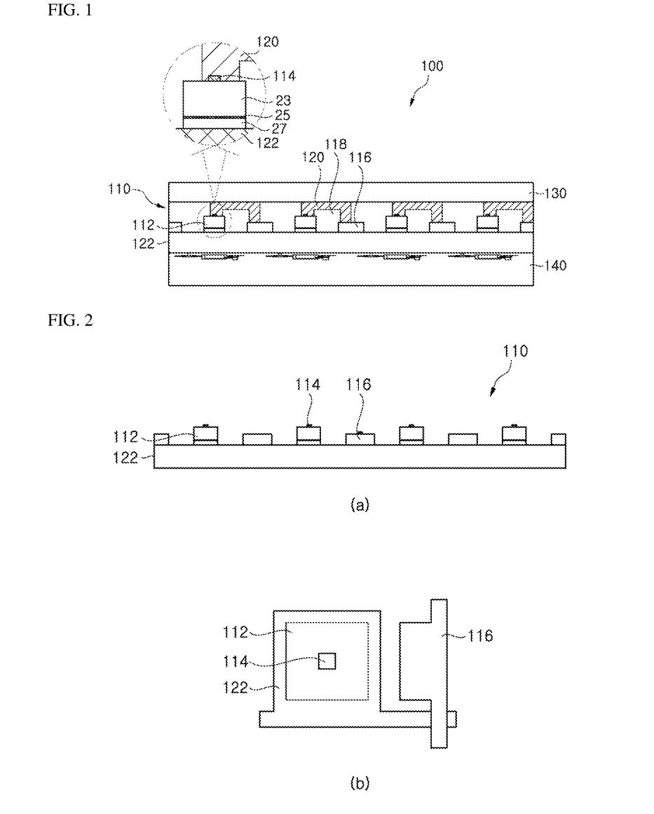

FIG. 1 is a cross-sectional view of a display apparatus according to one exemplary embodiment of the present invention.

Referring to FIG. 1, the display apparatus 100 according to the exemplary embodiment includes a light emitting diode part 110 and a TFT panel part 130.

The light emitting part 110 includes light emitting diodes 112, electrodes 114, substrate electrodes 116, an insulating portion 118, connection electrodes 120, and a substrate 122.

The light emitting diodes 112 are provided in plural and arranged at regular intervals on the substrate 122. For example, the plural light emitting diodes 112 may be arranged at constant intervals in rows and columns. With this arrangement, the plural light emitting diodes 112 may form a plurality of pixels on the display apparatus 100. In this exemplary embodiment, one pixel may be composed of three or four subpixels, in which one light emitting diode 112 is disposed in each subpixel. Although the following description will be given of the structure wherein one light emitting diode 112 is disposed in each subpixel, it should be understood that two or more light emitting diodes 112 may be provided to one subpixel, as needed.

Here, each of the subpixels may have a larger size than the light emitting diode disposed in the corresponding subpixel and the subpixels may have the same size.

In the display apparatus 100 according to this exemplary embodiment, when power is applied to each of the light emitting diodes 112, the light emitting diodes 112 can be turned on or off by power applied thereto and the light emitting part 110 can be driven. That is, in a structure wherein the light emitting diodes 112 of the light emitting part 110 include a blue light emitting diode, a green light emitting diode and a red light emitting diode, the light emitting part 110 of the display apparatus 100 can be driven without a separate LCD. Here, the blue light emitting diode may be a diode emitting blue light and the green light emitting diode may be a diode emitting green light. In addition, the red light emitting diode may be a GaAs-based red light emitting diode or may be a combination of a blue light emitting diode and red phosphors. The red phosphors can emit red light through wavelength conversion of blue light emitted from the blue light emitting diode.

In this exemplary embodiment, each of the light emitting diodes 112 may include an n-type semiconductor layer 23, an active layer 25, and a p-type semiconductor layer 27. Here, each of the n-type semiconductor layer 23, the active layer 25 and the p-type semiconductor layer 27 may include Group III-V based compound semiconductors. By way of example, these semiconductor layers may include nitride semiconductors such as (Al, Ga, In)N, (Al, Ga, In)As, or (Al, Ga, In)P. In other exemplary embodiments, locations of the n-type semiconductor layer 23 and the p-type semiconductor layer 27 can be interchanged.

The n-type semiconductor layer 23 may be a conductive semiconductor layer including an n-type dopant (for example, Si) and the p-type semiconductor layer 27 may be a conductive semiconductor layer including a p-type dopant (for example, Mg). The active layer 25 is interposed between the n-type semiconductor layer 23 and the p-type semiconductor layer 27, and may have a multi-quantum well (MQW) structure. The composition of the active layer 25 may be determined so as to emit light having a desired peak wavelength.

In this exemplary embodiment, each of the light emitting diodes 112 may have the shape of a vertical type light emitting diode. In this structure, an n-type electrode may be formed on an outer surface of the n-type semiconductor layer 23 and a p-type electrode may be formed on an outer surface of the p-type semiconductor layer 27. The following description will be given of the structure wherein the p-type electrode is omitted and the n-type electrode is disposed as the electrode 114 on the n-type semiconductor layer 27. The electrodes 114 are disposed on the n-type semiconductor layer 27 and each of the electrodes 114 may have a smaller width than the n-type semiconductor layer 27.

The substrate electrodes 116 may be arranged to define a region for one subpixel and exhibit electrical conductivity. The substrate electrodes 116 may be regularly arranged on the substrate 122 and may be electrically connected to each other. Each of regions defined by the plurality of substrate electrodes 116 regularly arranged on the substrate may correspond to one subpixel and each of the light emitting diodes 112 may be disposed between the substrate electrodes 116 regularly arranged on the substrate.

In this exemplary embodiment, the substrate electrodes 116 have a smaller height than the light emitting diodes 112. Alternatively, the substrate electrodes 116 may have a greater height than the light emitting diodes 112, as needed. In the structure wherein the substrate electrodes 116 have a greater height than the light emitting diodes 112, light emitted from each of the light emitting diodes 112 is reflected by the substrate electrode 116 to be emitted upward from the light emitting diode 112 without mixing with light from other light emitting diodes 112 adjacent thereto. Each of the substrate electrodes 116 may have an inclined side surface.

The insulating portion 118 may be interposed between the light emitting diode 112 and the substrate electrode 116 and prevent direct electrical contact therebetween. The insulating portion 118 may be disposed to cover a portion of an upper surface and a side surface of the light emitting diode 112 while covering a portion of an upper surface and a side surface of the substrate electrode 116. When the insulating portion 118 is disposed to cover the upper surfaces of the light emitting diodes 112, the insulating portion 118 may not contact the electrodes 114.

In this exemplary embodiment, the insulating portion 118 may be printed by screen printing using a micro-ink jet printer. Here, the insulating portion 118 may include a transparent insulating epoxy. The insulating portion 118 may be interposed between the light emitting diodes 112 and the substrate electrodes 116 through local printing using the micro-ink jet printer, or may be formed along the light emitting diodes 112 and the substrate electrodes 116 through continuous printing using the micro-ink jet printer, as needed.

The substrate 122 serves to support the light emitting part 110 and may be selected from various kinds of substrates. The substrate may have a structure in which an insulating layer and a metal layer are alternately stacked one above another on the TFT panel part. With this structure, the substrate can electrically connect the light emitting part to the TFT panel part.

The substrate 122 exhibits insulating properties in its entirety and may include conductive members in some regions thereof. Here, the conductive members may be disposed to pass through the substrate 122 from an upper surface of the substrate to a lower surface thereof to allow electrical conduction between the upper and lower surfaces thereof. Such a substrate 122 may be manufactured by forming a plurality of holes in an electrically insulating substrate from an upper surface of the substrate to a lower surface thereof, followed by filling the holes with a conductive material (for example, at least one of Cu, Au and Ag). Accordingly, the substrate 122 includes a plurality of conductive members electrically connected to each other.

In the structure wherein the substrate 122 includes the conductive members, the plurality of light emitting diodes 112 may be disposed on the conductive members of the substrate 122, respectively. The p-type semiconductor layer 27 of the light emitting diode 112 may be secured to the conductive member of the substrate 122 by a bonding portion. In addition, the substrate electrodes 116 may be electrically connected to the conductive members of the substrate 122 on which the light emitting diodes 112 are not disposed.

The substrate 122 may be a flexible substrate and an insulating portion of the substrate 122 may include at least one of PDMS (poly dimethylpolysiloxane), polyimide and ceramic materials. Since the substrate 122 has flexibility, the display apparatus 100 may have a flat shape or a curved shape.

The connection electrodes 120 may electrically contact the electrodes 114 of the light emitting diodes 112 and may also electrically contact the substrate electrodes 116. In this exemplary embodiment, each of the connection electrodes 120 may be disposed on the insulating portion 118 to cover the electrode 114 and a portion of the substrate electrode 116. With this structure, the electrodes 114 may be electrically connected to the substrate electrodes 116 by the connection electrodes 120, respectively.

Like the insulating portion 118, the connection electrodes 120 may be formed by screen printing using a micro-ink jet printer. Here, the connection electrodes 120 may include a transparent conductive epoxy, and may include transparent conductors such as ITO, ZnO and Ag nanowires, as needed. Although the connection electrodes 120 are formed by screen printing for electrical connection between the electrodes 114 and the substrate electrodes 116, side surfaces of the light emitting diodes 112 can be electrically insulated from the substrate electrodes 116 by the insulating portion 118 disposed under the connection electrodes 120.

In addition, although each of the insulating portion 118 and the connection electrodes 120 is illustrated as having a certain thickness in the drawings, the thickness of each of the insulating portion 118 and the connection electrodes 120 can be adjusted as needed, since the insulating portion 118 and the connection electrodes 120 are formed by screen printing. Alternatively, in a thin film process such as chemical vapor deposition (CVD) or physical vapor deposition (PCD), the insulating portion 118 may be formed by conformal coating.

The insulating portion 118 may be formed to a sufficient thickness to completely cover the side surfaces of the light emitting diodes 112. In this exemplary embodiment, the insulating portion 118 is disposed only at a location corresponding to the connection electrode 120 formed thereon. Alternatively, the insulating portion 118 may be disposed between the light emitting diode 112 and the substrate electrode 116, at which the connection electrode 120 is not disposed.

The TFT panel part 140 is coupled to the light emitting part 110 and supplies power to the light emitting part 110. The TFT panel part 140 can control power supply to the light emitting part 110 to allow only some of the light emitting diodes 112 in the light emitting part 110 to emit light and can control the intensity of light emitted by the light emitting diodes 112.

The TFT panel part 140 may have a TFT drive circuit therein. The TFT drive circuit may be a circuit for driving an active matrix (AM) or a circuit for driving a passive matrix (PM).

The TFT drive circuit may be electrically connected to the light emitting diodes 112 and the substrate electrodes 116 of the light emitting part 110. The TFT drive circuit may be electrically connected to the light emitting diodes 112 and the substrate electrodes 116 through the substrate 122.

Further, in this exemplary embodiment, the light emitting part 110 may be electrically connected to the TFT panel part 140 via an anisotropic conductive film. The anisotropic conductive film may include an adhesive organic insulating material and may contain conductive particles uniformly dispersed therein to achieve electrical connection. The anisotropic conductive film exhibits electrical conductivity in the thickness direction thereof and insulating properties in the plane direction thereof. In addition, the anisotropic conductive film exhibits adhesive properties. With this structure, the anisotropic conductive film can bond the light emitting part 110 and the TFT panel part 140 to each other. Such an anisotropic conductive film may be advantageously used to connect electrodes which are difficult to solder at high temperature.

In this exemplary embodiment, the display apparatus 100 may include the light emitting part 110 and the TFT panel part 140, as described above, and may further include a protective substrate 130 on the light emitting part 110. The protective substrate 130 may directly contact the light emitting part 110 to protect the light emitting part 110 from an external environment.

The display apparatus 100 may further include a light conversion part between the light emitting part 110 and the protective substrate 130. The light conversion part may permit light emitted from the light emitting part 110 to pass therethrough, may emit light through wavelength conversion of the light emitted from the light emitting part 110, or may block light having a certain wavelength. To this end, the light conversion part may include at least one of a phosphor layer and a color filter. In the structure wherein the light emitting diodes 112 of the light emitting part 110 are blue light emitting diodes, the light conversion part may include a green phosphor layer emitting green light through wavelength conversion of the blue light and a red phosphor layer emitting red light through wavelength conversion of the blue light. With this structure, the display apparatus can emit blue light, green light, and red light.

The color filter includes at least one of a blue light portion capable of blocking light of wavelengths other than blue light, a green light portion capable of blocking light of wavelengths other than green light, and a green light portion capable of blocking light of wavelengths other than red light.

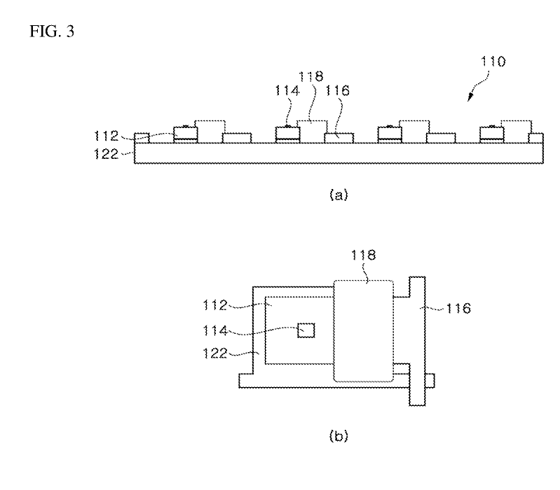

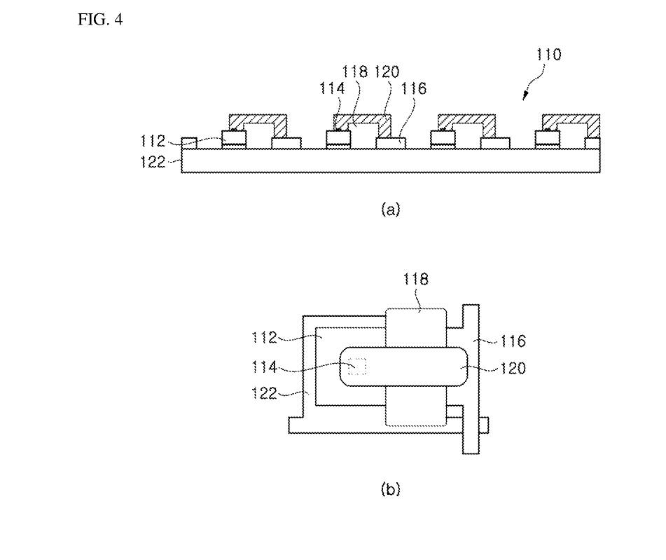

FIG. 2 to FIG. 4 are views illustrating a process of connecting electrodes of the light emitting part of the display apparatus according to the exemplary embodiment. FIG. 2 shows a cross-sectional view and a top view of the light emitting part of the display apparatus, FIG. 3 shows a cross-sectional view and a top view of the light emitting part on which an insulating portion 118 is formed, and FIG. 4 shows a cross-sectional view and a top view of the light emitting part in which a connection electrode 120 is formed on the insulating portion 118.

Referring to FIGS. 2(a) and (b), a plurality of light emitting diodes 112 and a plurality of substrate electrodes 116 are regularly arranged on a substrate 122. Each of the light emitting diodes 112 may be disposed between the substrate electrodes 116. The light emitting diodes 112 and the substrate electrodes 116 may be separated at constant intervals from each other.

Referring to FIG. 3(a), the insulating portion 118 may be formed between each of the light emitting diodes 112 and each of the substrate electrodes 116. The insulating portion 118 may be formed by printing using a micro-ink jet printer. To form the insulating portion 118 by printing using the micro-ink jet printer, a transparent insulating epoxy may be printed between the light emitting diode 112 and the substrate electrode 116 to cover parts of the light emitting diode 112 and the substrate electrode 116 while covering the substrate 122.

As shown in FIG. 3(b), the insulating portion 118 may be printed only at a location at which a corresponding light emitting diode 112 is disposed. Alternatively, the insulating portion 118 may be printed so as to continuously cover part of the plural light emitting diodes 112, as needed.

The insulating portion 118 may be formed of a transparent material so as to allow light emitted from the light emitting diodes 112 to pass therethrough, and an epoxy material may be used for printing of the insulation portion 118 using the micro-ink jet printer. Alternatively, any material enabling printing using a micro-ink jet printer may be used. The insulating portion 118 may be formed to a greater thickness than or the same thickness as the light emitting diodes 112.

The insulating portion 118 may be deposited by various method as well as printing as described above. As described above, the insulating portion 118 may be printed using the micro-ink jet printer, or may be formed by depositing an insulating portion through vapor deposition such as chemical vapor deposition (CVD) or physical vapor deposition (PVD), followed by patterning. Alternatively, the insulating portion 118 may be formed by depositing an insulating material such as a polymer resin through thermal vaporization deposition, followed by patterning. Here, a printed insulating portion may be formed of a photosensitive polyimide or a photosensitive organic insulating material such as SU-8 and BCB.

Referring to FIG. 4(a), the connection electrodes 120 may be formed over the insulating portion 118. The connection electrodes 120 are disposed to cover the insulating portion 118 while electrically connecting electrodes 114 disposed on the light emitting diodes 112 to substrate electrodes 116 each separated from the light emitting diode 112 in in a lateral direction. Each of the connection electrodes 120 may be formed to cover the entirety of the electrode 114 while partially covering the substrate electrode 116.

Referring to FIG. 4(b), each of the connection electrodes 120 is disposed on the insulating portion 118 to intersect the insulating portion 118 and electrically connects the electrode 114 to the substrate electrode 116. Here, the connection electrode 120 is formed to have one side covering the electrode 114 disposed on the light emitting diode 112 without passing over the light emitting diode 112. That is, one end of the connection electrode 120 in the longitudinal direction may be placed on the light emitting diode 112. In addition, the other side of the connection electrode 120 is disposed on the substrate electrode 116 without passing over the substrate electrode 116. That is, the other end of the connection electrode 120 in the longitudinal direction may be placed on the substrate electrode 116. In other words, each of the connection electrodes 120 is formed to electrically connect the light emitting diode 112 to the substrate electrode 116 adjacent to the light emitting diode 112.

Accordingly, the connection electrodes 120 may be provided to the light emitting diodes 112, respectively, and thus, the number of connection electrodes may correspond to the number of light emitting diodes 112.

Although certain exemplary embodiments have been described herein, it should be understood by those skilled in the art that these embodiments are given by way of illustration only, and that various modifications, variations, and alterations can be made without departing from the spirit and scope of the invention. Therefore, the scope of the invention should be limited only by the accompanying claims and equivalents thereof.

<List of Reference Numerals>

| | |
|---|---|
| 100: display apparatus | |
| 110: light emitting part | |
| 112: light emitting diode | 23: n-type semiconductor layer |
| 25: active layer | 27: p-type semiconductor layer |
| 114: electrode | 116: substrate electrode |
| 118: insulating portion | 120: connection electrode |
| 122: substrate | |
| 130: protective substrate | 140: TFT panel part |

What is claimed is:

1. A display apparatus comprising:
a light emitting part comprising a plurality of light emitting diodes regularly arranged thereon; and
a TFT panel part comprising a plurality of TFTs driving the plurality of light emitting diodes,
wherein the light emitting part comprises a substrate; a plurality of electrodes regularly arranged on the substrate; the plurality of light emitting diodes regularly arranged on the substrate and separated from the plurality of electrodes; and a plurality of printed connection electrodes electrically connecting the plurality of electrodes to the plurality of light emitting diodes, respectively.

2. The display apparatus according to claim 1, further comprising:
a printed insulating portion interposed between the plurality of electrodes and the plurality of light emitting diodes,
wherein each of the printed connection electrodes is disposed on the printed insulating portion.

3. The display apparatus according to claim 2, wherein the printed insulating portion has the same or greater thickness than the light emitting diodes.

4. The display apparatus according to claim 3, wherein the printed insulating portion is formed by conformal coating.

5. The display apparatus according to claim 2, wherein the printed insulating portion is formed of a transparent material.

6. The display apparatus according to claim 1, wherein each of the printed connection electrodes electrically connects an electrode to a light emitting diode adjacent to the electrode among the plurality of electrodes and the plurality of light emitting diodes.

7. The display apparatus according to claim 1, wherein the plurality of printed connection electrodes is formed of a transparent material.

8. The display apparatus according to claim 2, wherein the printed insulating portion or each of the printed connection electrodes is formed by printing using a micro-ink jet printer.

9. The display apparatus according to claim 1,
wherein each of the electrodes is a second electrode, and
wherein each of the light emitting diodes comprises a first conductivity type semiconductor layer, a second conductivity type semiconductor layer, an active layer interposed between the first and second conductivity type semiconductor layers, and a first electrode disposed on the second conductivity type semiconductor layer.

10. A method of connecting electrodes of a display apparatus, comprising:
printing a printed insulating portion between a plurality of light emitting diodes and a plurality of electrodes regularly arranged on a substrate using a micro-ink jet printer; and
printing a plurality of printed connection electrodes on the printed insulating portion using a micro-ink jet printer to electrically connect the plurality of light emitting diodes to the plurality of electrodes, respectively.

11. The method according to claim 10, wherein the printed insulating portion is formed of a transparent insulating epoxy.

12. The method according to claim 10, wherein the printed connection electrodes are formed of a transparent conductive epoxy.

13. The method according to claim 10, wherein the printed connection electrodes are formed of at least one of ITO, ZnO and Ag nanowires.

14. The method according to claim 10, wherein printing the printed insulating portion comprises printing a plurality of printed insulating portions between the plurality of light emitting diodes and the plurality of electrodes, respectively, and the printed insulating portions are spaced apart from each other.

15. The method according to claim 10, wherein the printed connection electrodes are spaced apart from each other.
